(19) United States
(12) Patent Application Publication
(10) Pub. No.: US 2020/0243592 A1
(43) Pub. Date: Jul. 30, 2020

(54) ACTIVE MATRIX SUBSTRATE, AND INSPECTION DEVICE FOR THE ACTIVE MATRIX SUBSTRATE

(71) Applicant: Sharp Kabushiki Kaisha, Sakai City (JP)

(72) Inventor: KOHZOH TAKAHASHI, Sakai City (JP)

(21) Appl. No.: 16/775,691

(22) Filed: Jan. 29, 2020

Related U.S. Application Data
(60) Provisional application No. 62/798,736, filed on Jan. 30, 2019.

(51) Int. Cl. H01L 27/146; H01L 21/66; G01R 31/317

(52) U.S. Cl. CPC H01L 27/14636; G01R 31/31713; H01L 27/14663; H01L 22/32

(57) ABSTRACT

An active matrix substrate includes a plurality of gate lines, a plurality of data lines, a first terminal group having a plurality of terminals connected to first ends of the plurality of gate lines, and a second terminal group having a plurality of terminals connected to first ends of the plurality of data lines. The active matrix substrate further includes a plurality of inspection terminals disposed dispersedly between the plurality of terminals in the terminal group as at least one of the first terminal group and the second terminal group.

### TECHNICAL FIELD

The present disclosure relates to an active matrix substrate, and an inspection device for the active matrix substrate.

### BACKGROUND ART

JP 2008-151954 A discloses an inspection device configured to detect any defect of scanning lines or data lines in a display panel, during a production process of the display panel. There is also disclosed an inspection method with use of this inspection device, and the inspection method includes connecting a probe to each terminal included in a terminal group connected to the scanning lines or the data lines and applying predetermined voltage to each of the probes to operate a pixel circuit provided at the display panel, upon execution of inspection (hereinafter, the present inspection) for detection of any defect of the scanning lines or the data lines. According to JP 2008-151954 A, two terminals disposed at both ends among the terminals connected to the scanning lines or the data lines are internally wired to each other so as to be equal in potential. If the probes connected to these two terminals have a resistance value exceeding a predetermined resistance value prior to the present inspection, either one of these probes is determined as having improper connection or being positionally displaced from the corresponding terminal.

As disclosed in JP 2008-151954 A, the present inspection can be appropriately executed with preliminary detection of a connection state between the corresponding probe and each of the two terminals disposed at the both ends of the terminal group connected to the scanning lines or the data lines and positional adjustment of the probes prior to the present inspection. According to JP 2008-151954 A, the terminals at the both ends of the terminal group connected to the scanning lines or the data lines need to be wired so as to be equal in potential, which will lead to less design flexibility of a terminal region.

### SUMMARY

In view of the above problem, there has been devised an active matrix substrate including: a substrate; a plurality of gate lines arrayed in a direction on the substrate; a plurality of data lines arrayed to cross the plurality of gate lines on the substrate; a first terminal group including a plurality of terminals arrayed and connected to first ends of the plurality of gate lines; a second terminal group including a plurality of terminals arrayed and connected to first ends of the plurality of data lines; and a plurality of inspection terminals disposed dispersedly between the plurality of terminals in at least one of the first terminal group and the second terminal group and wired to each other.

This configuration is less likely to cause deterioration in design flexibility of a terminal region, and enables appropriate execution of operation checking inspection.

### BRIEF DESCRIPTION OF DRAWINGS

FIG. 1 is a pattern diagram of an active matrix substrate and inspection device for the active matrix substrate according to a first embodiment.

FIG. 2 is a plan view depicting a schematic configuration of the active matrix substrate in FIG. 1.

FIG. 3 is an equivalent circuit diagram of pixels in an imaging region depicted in FIG. 2.

FIG. 4 is a pattern diagram depicting a configuration of each tab 15a depicted in FIG. 2.

FIG. 5 is a pattern diagram depicting a configuration of each tab 15b depicted in FIG. 2.

FIG. 6 is a pattern diagram depicting exemplary configurations of part of the tabs 15a depicted in FIG. 2 and part of inspection device 2 depicted in FIG. 1.

FIG. 7 is a pattern diagram depicting schematic configurations of tabs 15a on an active matrix substrate and inspection device according to a second embodiment.

### DESCRIPTION OF EMBODIMENTS

Described in detail below with reference to the drawings are an active matrix substrate, and an inspection device for the active matrix substrate according to each embodiment. Identical or corresponding parts in the drawings will be denoted by an identical reference sign and will not be described repeatedly.

### First Embodiment

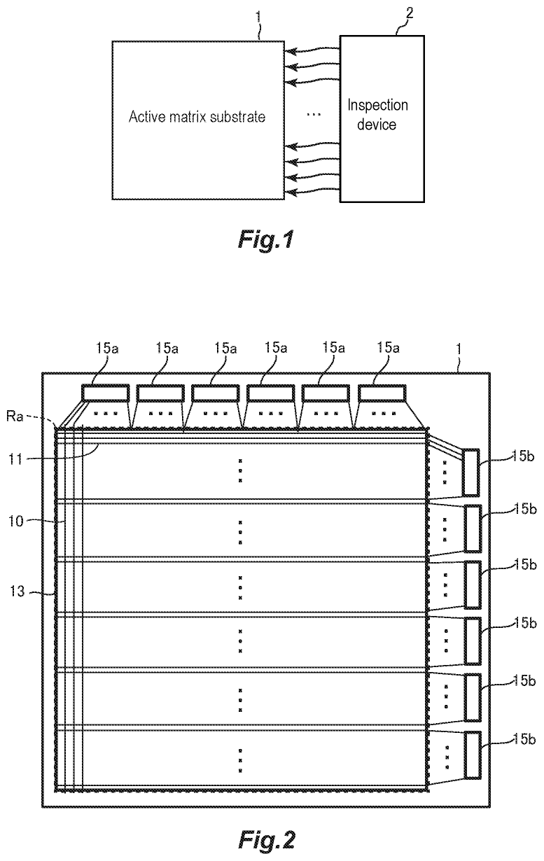

FIG. 1 is a pattern diagram of an active matrix substrate 1 and an inspection device 2 for the active matrix substrate 1 according to the present embodiment. The present embodiment relates to inspecting, by means of the inspection device 2, the active matrix substrate 1 to be subjected to operation checking inspection to check whether or not the active matrix substrate 1 is in a state of being appropriately subjected to the operation checking inspection, in a production process or the like of the active matrix substrate 1 included in an X-ray imaging panel or the like. Such inspection executed by the inspection device 2 will hereinafter be called preliminary inspection.

### Configuration

FIG. 2 is a plan view depicting a schematic configuration of the active matrix substrate 1. The active matrix substrate 1 can be included in an X-ray imaging panel or the like. Specifically, the X-ray imaging panel can be produced through disposing, on one of surfaces of the active matrix substrate 1, a scintillator configured to convert X-rays having transmitted through a shooting target to fluorescence (scintillation light). The active matrix substrate 1 will be specifically described below in terms of its configuration.

The active matrix substrate 1 includes a plurality of data lines 10 and a plurality of gate lines 11 crossing the plurality of data lines 10. The data lines 10 and the gate lines 11 each include 3072 lines in this example. The active matrix substrate 1 has an imaging region Ra including a plurality of regions (hereinafter, pixels) each surrounded with the data lines 10 and the gate lines 11.

The imaging region Ra is provided therein with a bias wire 13 surrounding the imaging region Ra. Although not depicted in this figure, the pixels are each provided therein with a wire led from the bias wire 13. The wires led from the bias wire 13 and disposed in the pixels will hereinafter also be collectively called the bias wire 13.

Outside the imaging region Ra, there is a region disposed adjacent to first ends of the data lines 10 and including N (N is a natural number of two or more) tabs 15a, and there is further a region disposed adjacent to first ends of the gate lines 11 and including N tabs 15b. The tabs 15a and the tabs 15b each include 12 tabs in this example. The tabs 15a and 15b will be described in detail later.

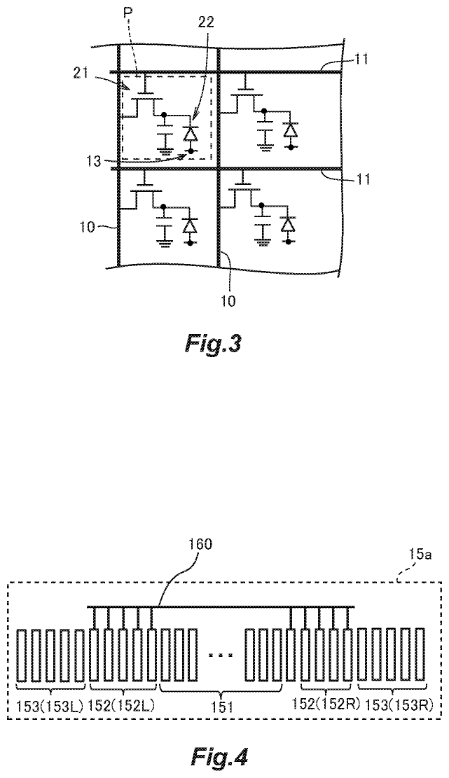

The pixels in the imaging region Ra will be described next in terms of their configuration. FIG. 3 is an equivalent circuit diagram depicting the configuration of the pixels. FIG. 3 depicts pixels P each including a thin film transistor (TFT) 21 and a photoelectric conversion element 22.

The photoelectric conversion element 22 includes a PIN photodiode and a pair of electrodes (a cathode electrode and an anode electrode). The TFT 21 includes a source connected to a corresponding one of the data lines 10, and a drain connected to the cathode electrode of the photoelectric conversion element 22. The anode electrode of the photoelectric conversion element 22 is connected to the bias wire 13. The bias wire 13 disposed in each of the pixels is connected to the anode electrode of the photoelectric conversion element 22 via an interlayer insulating film (not depicted).

Though not depicted in FIG. 3, the active matrix substrate 1 is connected to a drive circuit configured to apply scanning voltage to scan the gate lines 11, and a readout circuit configured to read electric charge converted by the PIN photodiode out of each of the data lines 10. When the TFT 21 connected to the scanned gate line 11 comes into an ON state, an electric signal according to the electric charge converted at the photoelectric conversion element 22 is outputted to the readout circuit via the data line 10.

Description is next made to the tabs 15a and 15b according to the present embodiment.

FIG. 4 is a pattern diagram depicting a configuration of one of the tabs 15a. As depicted in FIG. 4, the tab 15a includes a plurality of data terminals 151, a plurality of bias terminals 152, and a plurality of dummy terminals 153.

The data terminals 151 are each connected to the first end of a different one of the data lines 10. As described above, in this example, the data lines 10 include 3072 lines, the tabs 15a include 12 tabs, and the tabs 15a are each provided with 256 data terminals 151.

The tabs 15a each include ten bias terminals 152 (152L and 152R) interposing the 256 data terminals 151 (hereinafter, a data terminal group), and ten dummy terminals 153 (153L and 153R) interposing the bias terminals 152L and 152R. In other words, the data terminal group is disposed at the center, and five bias terminals 152L and five bias terminals 152R as well as five dummy terminals 153L and five dummy terminals 153R are disposed symmetrically about an array direction of the data terminals 151. The single tab 15a is provided with 276 terminals in total in this example.

The terminals each have about 40 μm or the like in width and are disposed at constant intervals of about 70 μm or the like.

The ten bias terminals 152L and 152R are connected to the bias wire 13. The bias terminals 152L and 152R are wired to each other via a wire 160.

The ten dummy terminals 153 (153L and 153R) serve as spare terminals not electrically connected to any other element in this example.

Though not depicted in FIG. 4, the remaining tabs 15a are configured identically to the tab 15a described above. The bias terminals 152 in each of the tabs 15a are each wired to the remaining bias terminals 152 in the identical tab 15a as well as to the bias terminals 152 in the other tabs 15a via the wire 160.

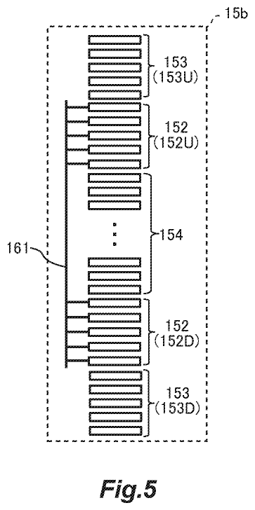

The tabs 15b will be described next in terms of their configuration. FIG. 5 is a pattern diagram depicting the configuration of one of the tabs 15b. As depicted in FIG. 5, the tab 15b includes a plurality of gate terminals 154, a plurality of bias terminals 152, and a plurality of dummy terminals 153.

The gate terminals 154 are each connected to a first end of a different one of the gate lines 11. As described above, in the present embodiment, the gate lines 11 include 3072 lines, the tabs 15b include 12 tabs, and the tabs 15b are each provided with 256 gate terminals 154.

The tabs 15b each include ten bias terminals 152 (152U and 152D) interposing the 256 gate terminals 154 (hereinafter, a gate terminal group), and ten dummy terminals 153 (153U and 153D) interposing the bias terminals 152U and 152D. In other words, the gate terminal group is disposed at the center, and five bias terminals 152U and five bias terminals 152D as well as five dummy terminals 153U and five dummy terminals 153D are disposed symmetrically about an array direction of the gate terminals 154. The single tab 15b is provided with 276 terminals in total in this example.

The ten bias terminals 152 (152U and 152D) are connected to the bias wire 13. The bias terminals 152U and 152D are wired to each other via a wire 161. The wire 161 may be electrically connected to the wire 160 (see FIG. 4).

The ten dummy terminals 153 (153L and 153R) serve as spare terminals not electrically connected to any other element in this example.

Though not depicted in FIG. 5, the remaining tabs 15b are configured identically to the tab 15b described above. The bias terminals 152 in each of the tabs 15b are each wired to the remaining bias terminals 152 in the identical tab 15b as well as to the bias terminals 152 in the other tabs 15b via the wire 161.

Imaging by means of the active matrix substrate 1 includes application, to each of the bias terminals 152, of voltage having reverse bias with respect to the photoelectric conversion elements 22. Two of the bias terminals 152 in each of the tabs 15a and 15b are used for the preliminary inspection executed prior to imaging inspection of the active matrix substrate 1. Description is made specifically exemplarily below to the inspection device 2 configured to execute the preliminary inspection and an inspection method.

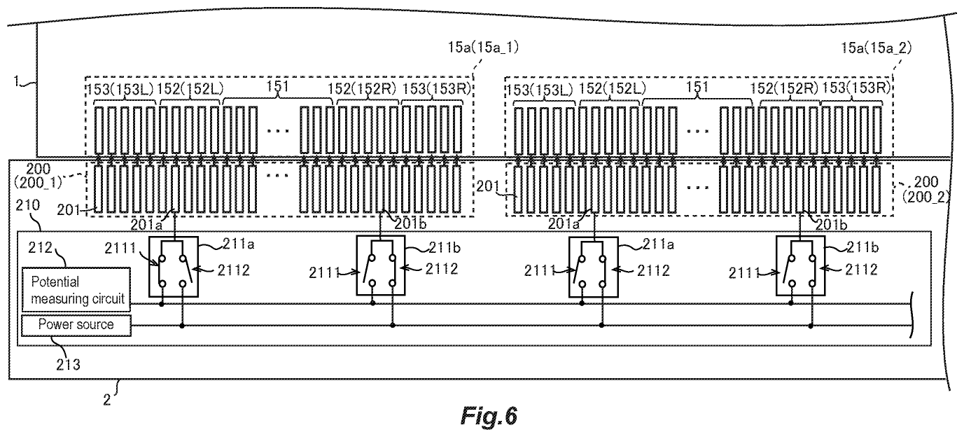

FIG. 6 is a pattern diagram depicting exemplary configurations of part of the tabs 15a and part of the inspection device 2. As depicted in FIG. 6, the inspection device 2 includes a single probe group 200 for each of the tabs 15a. Though not depicted in FIG. 6, the inspection device 2 includes the single probe group 200 for each of the tabs 15a and each of the tabs 15b.

The probe group 200 includes probes 201 of the number equal to the number of the terminals provided in the tab 15a or 15b. The single probe group 200 include 276 probes 201 in this example.

When the active matrix substrate 1 is preliminarily inspected by inspection device 2, the probes 201 in the probe group 200 for the tab 15a are made in contact with the terminals (the data terminals 151, the bias terminals 152L and 152R, and the dummy terminals 153L and 153R) in the tab 15a. Furthermore, the probes 201 in the probe group 200 for the tab 15b are made in contact with the terminals (the gate terminals 154, the bias terminals 152U and 152D, and the dummy terminals 153U and 153D) in the tab 15b.

A measuring circuit 210 includes a pair of switching circuits 211a and 211b for each of the probe groups 200, a potential measuring circuit 212, and a power source 213.

The switching circuit 211a is connected to one of the probes 201 (201a). The probe 201a is provided for one of the bias terminals 152L in the tab 15a.

The switching circuit 211b is connected to one of the probes 201 (201b) different from the probe 201a. The probe 201b is provided for one of the bias terminals 152R in the tab 15a.

In a case where the probes 201a and 201b connected to the switching circuits 211a and 211b are distinguished from the remaining probes 201, the probes 201a and 201b will be called measurement candidate probes.

The switching circuit 211a and the switching circuit 211b each have two switching elements 2111 and 2112 constituted by transistors or the like. The switching element 2111 is connected to the potential measuring circuit 212 whereas the switching element 2112 is connected to the power source 213. The switching elements 2111 and 2112 in each of the switching circuits 211a and 211b are controlled to be ON and OFF by a switching control circuit (not depicted).

The measuring circuit 210 sequentially measures voltage at all the measurement candidate probes (201a and 201b). FIG. 6 depicts ON and OFF states of the switching elements 2111 and 2112 upon potential measurement of the probe 201a in a probe group 200_1.

Upon potential measurement of the probe 201a in the probe group 200_1, the switching circuits 211a and 211b are controlled to be ON and OFF such that only the probe 201a in the probe group 200_1 is conducted to the potential measuring circuit 212. As depicted in FIG. 6, among the switching elements 2111 in all the switching circuits 211a and 211b, only the switching element 2111 in the switching circuit 211a connected to the probe 201a in the probe group 200_1 is switched ON and the switching elements 2111 in the remaining switching circuits 211a and 211b are switched OFF. Among all the switching elements 2112, only the switching element 2112 connected to the probe 201a in the probe group 200_1 is switched OFF and the remaining switching elements 2112 are switched ON. This achieves electrical connection between only the single measurement candidate probe as a potential measurement target and the potential measuring circuit 212, as well as electrical connection between the remaining measurement candidate probes and the power source 213. The single measurement candidate probe as the potential measurement target will hereinafter be conveniently called a measured probe 201P.

The potential measuring circuit 212 is connected to the switching elements 2111 in the switching circuits 211a and 211b. The potential measuring circuit 212 measures and outputs voltage at the measured probe 201P via the switching element 2111 having been switched ON.

The power source 213 is connected to the switching elements 2112 in the switching circuits 211a and 211b. The power source 213 applies, via the switching elements 2112 having been switched ON, bias voltage to the measurement candidate probes (201a and 201b) other than the measured probe 201P.

The preliminary inspection according to the present embodiment includes initially disposing the probe groups 200 in the inspection device 2 so as to be connected to the terminals in the tabs 15a or 15b on the active matrix substrate 1. Subsequently, the switching control circuit (not depicted) in the measuring circuit 210 selects the measured probe 201P from among the measurement candidate probes (201a or 201b) in the probe groups 200, and controls to switch ON the switching element 2111 connected to the measured probe 201P and switch OFF the switching element 2112 connected to the measured probe 201P. The switching control circuit further controls to switch OFF and ON the switching elements 2111 and the switching elements 2112, respectively, which are connected to the measurement candidate probes other than the measured probe 201P. The potential measuring circuit 212 then measures voltage at the measured probe 201P.

As described above, the bias terminals 152 (152L and 152R) in each of the tabs 15a are wired to each other (see FIG. 4). When the power source 213 applies bias voltage to the measurement candidate probes 201a and 201b other than the measured probe 201P, the bias voltage is applied to the bias terminals 152 via the measurement candidate probes. All the bias terminals 152 are accordingly made equal in potential via the measurement candidate probes. In a case where the measured probe 201P and the bias terminal 152 are in proper contact with each other, voltage at the measured probe 201P measured by the potential measuring circuit 212 is substantially equal to the bias voltage. In another case where the measured probe 201P and the bias terminal 152 are not in proper contact with each other, voltage at the measured probe 201P measured by the potential measuring circuit 212 is not equal to the bias voltage. Voltage measurement at each of the measurement candidate probes accordingly enables detection of whether or not the measurement candidate probe is in proper contact with the bias terminal, or whether or not the measurement candidate probe is displaced.

In the active matrix substrate 1 according to the present embodiment, the pair of bias terminals 152L and 152R interposing the data terminal group in each of the tabs 15a function as inspection terminals used for the preliminary inspection. The inspection device 2 includes, as the measurement candidate probes, the probes 201 for the inspection terminals on the active matrix substrate 1. Recent terminals have narrower pitches, and probing has also been getting more difficult. The terminals in the tabs 15a and 15b according to the present embodiment also have pitches as narrow as about 70 μm. Voltage measurement at the measurement candidate probes prior to imaging inspection enables improvement in probing accuracy and prevention of repeated imaging inspection.

The bias terminals 152 are used for the preliminary inspection in the present embodiment, without provision of any additional inspection terminal for inspection of whether or not each of the probes 201 is in proper contact with the corresponding terminal. Each of the bias terminals 152 used for the preliminary inspection in the present embodiment is substantially equal in shape and size to the other terminals adjacent to the bias terminal 152, which is less likely to restrict design of the tabs 15a and 15b.

The above description exemplifies the probe groups 200 for the tabs 15a. The inspection device 2 also includes the probe group 200 for each of the tabs 15b and the switching circuits 211a and 211b for each of the probe groups 200. In this case, the switching circuit 211a for each of the probe groups 200 is connected to the probe 201 (measurement candidate probe) provided for one of the bias terminals 152U (see FIG. 5) in a corresponding one of the tabs 15b. The switching circuit 211b for each of the probe groups 200 is connected to the probe 201 (measurement candidate probe) provided for one of the bias terminals 152D in the corresponding tab 15b. The inspection device 2 sequentially measures voltage at the measurement candidate probes for the tabs 15b to detect connection states of the measurement candidate probes in a manner similar to voltage measurement at the measurement candidate probes for the tabs 15a.

### Second Embodiment

The first embodiment described above exemplifies detection of the connection state between each of the two bias terminals 152 in each of the tabs 15a and 15b and a corresponding one of the measurement candidate probes during the preliminary inspection. Specifically, the two bias terminals 152 in each of the tabs 15a and 15b are adopted as the inspection terminals to detect the connection states of the two measurement candidate probes for these bias terminals 152. The present embodiment exemplifies adopting one of the bias terminals 152 in each of the tabs 15a and 15b as the inspection terminal to detect a connection state of a single measurement candidate probe for this bias terminal 152.

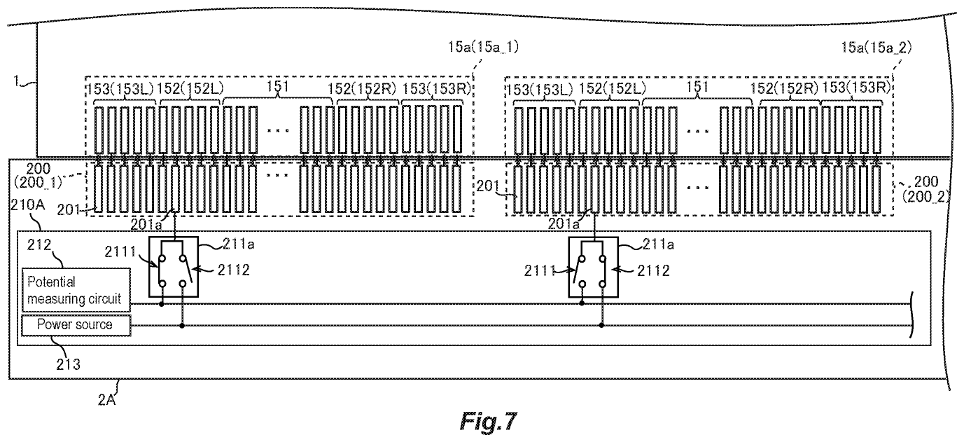

FIG. 7 is a pattern diagram depicting schematic configurations of part of the tabs 15a in the active matrix substrate 1 and inspection device according to the present embodiment. FIG. 7 depicts parts configured identically to those according to the first embodiment and denoted by reference signs identical to those in the first embodiment. The following description mainly relates to parts configured differently from those according to the first embodiment.

FIG. 7 depicts inspection device 2A including the probe group 200 for each of the tabs 15a and a measuring circuit 210A.

The measuring circuit 210A includes a single switching circuit 211a for each of the probe groups 200, and the switching circuit 211a is connected to the single probe 201a in the corresponding probe group 200. The probe 201a connected to the switching circuit 211a is a measurement candidate probe and is made in contact with one of the bias terminals 152L in the tab 15a during the preliminary inspection.

Though not depicted in FIG. 7, the probe group 200 in each of the tabs 15b includes the single measurement candidate probe 201a that is made in contact with one of the bias terminals 152 in the corresponding tab 15b during the preliminary inspection.

The measuring circuit 210A according to the present embodiment is thus different from the measuring circuit 210 according to the first embodiment in that the measuring circuit 210A does not include the switching circuit 211b.

Voltage at each of the measurement candidate probes 201a is measured in a manner similar to that according to the first embodiment. Specifically, the switching elements 2111 and 2112 in each of the switching circuits 211a are controlled to be ON or OFF such that the measurement candidate probes 201a sequentially have electrical connection to the potential measuring circuit 212, for sequential replacement of the measured probe 201P.

As described in the first embodiment, the bias terminals 152 in each of the tabs 15a and 15b are wired to each other. In a case where voltage at the measured probe 201P measured by the potential measuring circuit 212 is equal to bias voltage, the measured probe 201P is in proper contact with the corresponding bias terminal 152. In another case where the voltage measured by the potential measuring circuit 212 is not equal to the bias voltage, the measured probe 201P is not in proper contact with the corresponding bias terminal 152.

The single bias terminal 152 in each of the tabs 15a and 15b is used for the preliminary inspection to detect the connection state between the bias terminal 152 and the corresponding measurement candidate probe, in order to check prior to imaging inspection whether or not the probes 201 are positioned appropriately.

The bias terminal 152 used for the preliminary inspection in each of the tabs 15a may be one of the bias terminals 152R. The bias terminal 152 used for the preliminary inspection has only to be disposed at either one of ends of both sides of the data terminal group in each of the tabs 15a or the gate terminal group in each of the tabs 15b.

The embodiments described above are merely exemplified for implementation of the present invention. The present invention should not be limited to the above embodiments, but can be implemented with appropriate modifications to any of the above embodiments without departing from the spirit of the present invention. Modification examples of the present invention will be described below.

(1) The above embodiments exemplify using the bias terminal 152 for the preliminary inspection. The preliminary inspection may alternatively be executed with use of at least one of the dummy terminals 153 provided in each of the tabs 15a and 15b. In this case, the dummy terminals 153 used for the preliminary inspection are wired to each other such that these dummy terminals 153 are equal in potential. Specifically, at least one terminal used for the preliminary inspection has only to be disposed on either one of the sides of the data terminal group in each of the tabs 15a or the gate terminal group in each of the tabs 15b on the active matrix substrate 1.

The above embodiments exemplify the case where the bias terminal 152 is also adopted as the inspection terminal to which bias voltage is thus applied. The inspection terminals used for the preliminary inspection may have common potential such as predetermined reference potential (GND).

(2) The above embodiments exemplify using the bias terminal 152 in each of the tabs 15a and 15b for the preliminary inspection. Alternatively, at least either the tabs 15a or the tabs 15b have only to each include at least one inspection terminal used for the preliminary inspection.

(3) The above embodiments exemplify the active matrix substrate to be provided with a scintillator later. Alternatively, an X-ray imaging panel including an active matrix substrate and a scintillator disposed on one of surfaces of the active matrix substrate may have the configuration according to any one of the above embodiments. The scintillator is disposed on the surface of the active matrix substrate irradiated with X-rays.

(4) The above embodiments exemplify the active matrix substrate 1 included in an X-ray imaging panel. The configurations of the tabs 15a and 15b may also be applied to an active matrix substrate included in a display panel.

(5) The above embodiments should not be restricted by the above description in terms of the numbers of the data lines 10 and the gate lines 11 as well as the numbers of the tabs 15a and 15b. The terminal group connected to at least one wire group selected from the data lines 10 and the gate lines 11 according to any one of the embodiments has only to include a plurality of inspection terminals disposed dispersedly. Specifically, each of the inspection terminals may be provided for a single or a plurality of terminals adjacent to both sides of the inspection terminal, or may be provided for a single or a plurality of terminals adjacent to either one of the sides of the inspection terminal.

A single inspection terminal and a single or a plurality of terminals adjacent to the inspection terminal have any one of the following relations.

(i) The single inspection terminal is provided for the plurality of terminals adjacent to the both sides of the inspection terminal.

(ii) The single inspection terminal is provided for the single terminal adjacent to each of the sides of the inspection terminal.

(iii) The single inspection terminal is provided for the single terminal adjacent to either one of the sides of the inspection terminal.

(iv) The single inspection terminal is provided for the plurality of terminals adjacent to either one of the sides of the inspection terminal.

(v) The single inspection terminal is provided for the single terminal adjacent to either one of the sides of the inspection terminal and the plurality of terminals adjacent to the other side of the inspection terminal.

Potential measurement at the single inspection terminal accordingly enables determination of whether or not a probe for the single or the plurality of terminals adjacent to at least one of the sides of the inspection terminal is positioned appropriately.

The active matrix substrate and the inspection device described above can be recited as follows.

An active matrix substrate includes: a substrate; a plurality of gate lines arrayed in a direction on the substrate; a plurality of data lines arrayed to cross the plurality of gate lines on the substrate; a first terminal group including a plurality of terminals arrayed and connected to first ends of the plurality of gate lines; a second terminal group including a plurality of terminals arrayed and connected to first ends of the plurality of data lines; and a plurality of inspection terminals disposed dispersedly between the plurality of terminals in at least one of the first terminal group and the second terminal group and wired to each other (a first configuration).

The active matrix substrate according to the first configuration includes the first terminal group constituted by the terminals arrayed and connected to the gate lines, and the second terminal group constituted by the terminals arrayed and connected to the data lines. The active matrix substrate further includes the plurality of inspection terminals disposed dispersedly between the plurality of terminals in at least one of the terminal groups. The plurality of inspection terminals is wired to each other.

When operation checking inspection is executed to check whether or not voltage is appropriately applied to the gate lines or the data lines in a production process of the active matrix substrate, probes provided for the inspection are made in contact with at least one of the first terminal group and the second terminal group. In this configuration, the plurality of inspection terminals disposed dispersedly between the plurality of terminals in at least one of the terminal groups is wired to each other. If each of the inspection terminals is in proper contact with a corresponding one of the probes, the plurality of probes in contact with the plurality of inspection terminals are equal in potential. Potential detection at the probes for the inspection terminals accordingly enables checking whether or not the probes for the terminals in at least one of the terminal groups are positioned appropriately, for appropriate execution of the operation checking inspection. In the above configuration, the inspection terminals are dispersed between the plurality of terminals in at least one of the terminal groups. This achieves improvement in design flexibility of the terminals in comparison to a case where terminals at both ends of the plurality of terminals are wired to each other so as to be used for the inspection.

In the first configuration, each of the inspection terminals is optionally provided for a single or a plurality of terminals adjacent to the inspection terminal (a second configuration).

According to the second configuration, potential detection at the probe made in contact with each of the inspection terminals enables checking whether or not the single or the plurality of terminals adjacent to the inspection terminal is in proper contact with the corresponding probe.

In the first or second configuration, optionally, the active matrix substrate further includes: a plurality of photoelectric conversion elements disposed respectively in a plurality of pixels defined by the plurality of gate lines and the plurality of data lines; and a bias wire used to supply each of the photoelectric conversion elements with bias voltage; in which each of the inspection terminals is connected to the bias wire (a third configuration).

The inspection terminals are each connected to the bias wire in the third configuration. Each of the inspection terminals can thus also function as a terminal configured to apply bias voltage to the photoelectric conversion element in each of the pixels.

In the second or third configuration, each of the inspection terminals is optionally equal in shape and size to the single or the plurality of terminals adjacent to the inspection terminal (a fourth configuration).

The fourth configuration facilitates designing a region including the terminals in comparison to a case where each of the inspection terminals is different in shape and size from the single or the plurality of terminals adjacent to the inspection terminal.

An inspection device includes: a plurality of first probes provided respectively for the plurality of inspection terminals on the active matrix substrate according to any one of the first to fourth configurations; a plurality of second probes provided respectively for the plurality of terminals in at least one of the terminal groups on the active matrix substrate; and a measuring circuit connected to the plurality of first probes; in which the measuring circuit is configured to apply a predetermined voltage to the plurality of probes excluding one of the first probes and to detect a voltage at the one of the first probes (a fifth configuration).

According to the fifth configuration, the inspection device includes the first probes provided respectively for the inspection terminals on the active matrix substrate, and the second probes provided respectively for the terminals in at least one of the first terminal group and the second terminal group on the active matrix substrate. When the first probes are each in proper contact with a corresponding one of the terminals, all the first probes are equal in voltage. The first probes and the second probes can thus be positionally adjusted in accordance with voltage detection results at the first probes, for appropriate execution of the operation checking inspection.

### REFERENCE SIGN LIST

1 active matrix substrate

2 inspection device

10 data line

11 gate line

13 bias wire

15a, 15b tab

16a, 16b, 16c, 26a, 26c protective circuit

17a, 17b, 27a common wire

21 TFT

22 photoelectric conversion element

151 data terminal

152, 152L, 152R, 152U, 152D bias terminal

153, 153L, 153R, 153U, 153D dummy terminal

154 gate terminal

200 probe group

201 probe

211a, 211b switching circuit

212 potential measuring circuit

213 power source

2111, 2112 switching element

What is claimed is:

1. An active matrix substrate comprising:
a substrate;
a plurality of gate lines arrayed in a direction on the substrate;
a plurality of data lines arrayed to cross the plurality of gate lines on the substrate;
a first terminal group including a plurality of terminals arrayed and connected to first ends of the plurality of gate lines;
a second terminal group including a plurality of terminals arrayed and connected to first ends of the plurality of data lines; and
a plurality of inspection terminals disposed dispersedly between the plurality of terminals in at least one of the first terminal group and the second terminal group and wired to each other.

2. The active matrix substrate according to claim 1, wherein each of the inspection terminals is provided for a single or a plurality of terminals adjacent to the inspection terminal.

3. The active matrix substrate according to claim 1, further comprising:
a plurality of photoelectric conversion elements disposed respectively in a plurality of pixels defined by the plurality of gate lines and the plurality of data lines; and
a bias wire used to supply each of the photoelectric conversion elements with bias voltage; wherein
each of the inspection terminals is connected to the bias wire.

4. The active matrix substrate according to claim 2, wherein each of the inspection terminals is equal in shape and size to the single or the plurality of terminals adjacent to the inspection terminal.

5. An inspection device comprising:
a plurality of first probes provided respectively for the plurality of inspection terminals on the active matrix substrate according to claim 1;
a plurality of second probes provided respectively for the plurality of terminals in at least one of the terminal groups on the active matrix substrate; and
a measuring circuit connected to the plurality of first probes; wherein
the measuring circuit is configured to apply a predetermined voltage to the plurality of probes excluding one of the first probes and to detect a voltage at the one of the first probes.
